(19) United States
(12) Patent Application Publication
(10) Pub. No.: US 2007/0187141 A1
(43) Pub. Date: Aug. 16, 2007

(54) Circuit board with configurable ground link

(75) Inventor: Victor L. Bartholomew, Sherwood, OR (US)

Correspondence Address: Marguerite E. Gerstner;Tyco Electronics Corporation, 307 Constitution Drive, Menlo Park, CA, 94025-1164, US

(73) Assignee: TYCO ELECTRONICS CORPORATION

(21) Appl. No.: 11/354,515

(22) Filed: Feb. 15, 2006

(51) Int. Cl. H05K 1/11; H01R 12/04

(52) U.S. Cl. 174/261

(57) ABSTRACT

A circuit board for transitioning a cable to a connector comprises a circuit board having an outer surface. A circuit trace provided on the outer surface has a cable pad and a contact pad provided at different ends of the outer surface. A ground plane is held by the circuit board. A ground link on the outer surface is connected to the ground plane. The circuit trace and the ground link are located immediately adjacent one another. A resistive coating is provided over the circuit trace and the outer surface of the circuit board. The resistive coating has a mask aperture there-through exposing an uncoated portion of the circuit trace and exposing the ground link to the ground plane. A conductive jumper material is provided on the uncoated portion of the circuit trace and the ground link to render the circuit trace electrically common with the ground plane.

### BACKGROUND OF THE INVENTION

This invention relates generally to circuit boards, and more particularly, to circuit boards used in connectors to transition one type of cable to another.

Connector transition circuit boards are used in a variety of connector types to convey signals between cables, mother boards, daughter cards, backplanes and the like. For example, one end of the circuit board may be interconnected with one or more coaxial cables and the other end of the circuit board is interconnected with contacts in a connector or pads on a component circuit board. Currently available connector transition circuit boards typically do not have an internal ground reference. Thus, the connector transition circuit board generally forms a non-coaxial board-to-board wire interface. Today, high speed applications have increasing performance requirements and utilize higher and higher signal frequencies. The non-coaxial board-to-board wire interfaces formed in conventional connector transition circuit boards are inadequate for these high speed applications.

Further, existing connector systems with transition circuit boards are used with numerous different configurations of cables and component circuit boards. Each different cable and board configuration may have a unique signal and ground line configuration and a unique cable contact or pin pattern at the connector. Consequently, each different cable to board configuration has a unique signal and ground routing pattern through the connector between the cable and component circuit board. For example, one configuration may designate pins 1 and 10 as ground pins, while a second configuration may designate pins 4 and 20 as ground pins. Also, certain connectors may use insulation displacement contacts to terminate the wires within coaxial cables, while other connectors may not. Heretofore, connectors were designed for a specific application and configuration. It is expensive and undesirable to alter connector systems for each individual application and configuration, to change signal routing, to change pin-out patterns and create custom transition boards for different applications.

Therefore, a need exists for a transition circuit board for connectors that do not otherwise have an internal ground reference and that may be used in systems having different signal routing patterns with respect to each other. Certain embodiments of the present invention are intended to meet these needs and other objectives that will become apparent from the description and drawings set forth below.

### BRIEF DESCRIPTION OF THE INVENTION

In one embodiment, a circuit board for transitioning a cable to a connector comprises a circuit board having an outer surface. A circuit trace is provided on the outer surface of the circuit board and has a cable pad and a contact pad provided at different ends of the outer surface. A ground plane is held by the circuit board and a ground link is provided on the outer surface of the circuit board and is connected to the ground plane. The circuit trace and the ground link are located immediately adjacent one another. A resistive coating is provided over the circuit trace and the outer surface of the circuit board. The resistive coating has a mask aperture there-through exposing an uncoated portion of the circuit trace and exposing the ground link to the ground plane. A conductive jumper material is provided on the uncoated portion of the circuit trace and the ground link to render the circuit trace electrically common with the ground plane.

In another embodiment, an electrical connector comprises a connector and a circuit board that has an outer surface, a cable receiving end, and a contact mating end. The cable receiving end is configured to be joined to cables terminated at the circuit board and the contact mating end is configured to engage contacts. A circuit trace is provided on the outer surface of the circuit board and has a cable pad and a contact pad provided at different ends of the outer surface. A ground plane is held by the circuit board. A ground link is provided on the outer surface of the circuit board and is connected to the ground plane. The circuit trace and the ground link are located immediately adjacent to one another. A resistive coating is provided over the circuit trace and outer surface of the circuit board. The resistive coating has a mask aperture there-through exposing an uncoated portion of the circuit trace and exposing the ground link to the ground plane. A conductive jumper material is provided on the uncoated portion of the circuit trace and the ground link to render the circuit trace electrically common with the ground plane.

In another embodiment, a method of manufacturing a circuit board for transitioning a coaxial cable to a connector comprises forming a circuit board with a ground plane. A circuit trace is provided on an outer surface of the circuit board and has a cable pad and a contact pad at different ends of the outer surface. A ground link is provided between the outer surface and the ground plane. The circuit trace and outer surface of the circuit board are coated with a resistive coating. A portion of the circuit trace is covered during the coating step to prevent the resistive coating from covering the portion of the circuit trace and to form an uncoated portion of the circuit trace. The ground link is covered during the coating step to prevent the resistive coating from covering the ground link. The ground link and the uncoated portion of the circuit trace are located immediately adjacent to one another.

### BRIEF DESCRIPTION OF THE DRAWINGS

FIG. 1 illustrates a top layer of a circuit board which may be used to transition a cable to a connector formed in accordance with an embodiment of the present invention.

FIG. 2 illustrates a bottom layer of the circuit board in accordance with an embodiment of the present invention.

FIG. 3 illustrates a first ground plane formed as an intermediate layer of the circuit board in accordance with an embodiment of the present invention.

FIG. 4 illustrates a second ground plane formed as an intermediate layer of the circuit board in accordance with an embodiment of the present invention.

FIG. 5 illustrates a top solder mask which may be applied over the top layer of FIG. 1 in accordance with an embodiment of the present invention.

FIG. 6 illustrates a bottom solder mask which is applied over the bottom layer of FIG. 2 in accordance with an embodiment of the present invention.

FIG. 7 illustrates a first multilayer circuit board which may be used to transition a cable to a connector which does not have an internal ground reference.

FIG. 8 illustrates a second multiplayer circuit board which may be used to transition a cable to a connector which does not have an internal ground reference.

FIG. 9 illustrates an assembly of a circuit board and an insulation displacement connector which has been pressed thereon in accordance with an embodiment of the present invention.

FIG. 10 illustrates an assembly of a circuit board with an insulation displacement connector and ribbonized coaxial cable interconnected thereto in accordance with an embodiment of the present invention.

The foregoing summary, as well as the following detailed description of certain embodiments of the present invention, will be better understood when read in conjunction with the appended drawings. It should be understood that the present invention is not limited to the arrangements and instrumentality shown in the attached drawings.

### DETAILED DESCRIPTION OF THE INVENTION

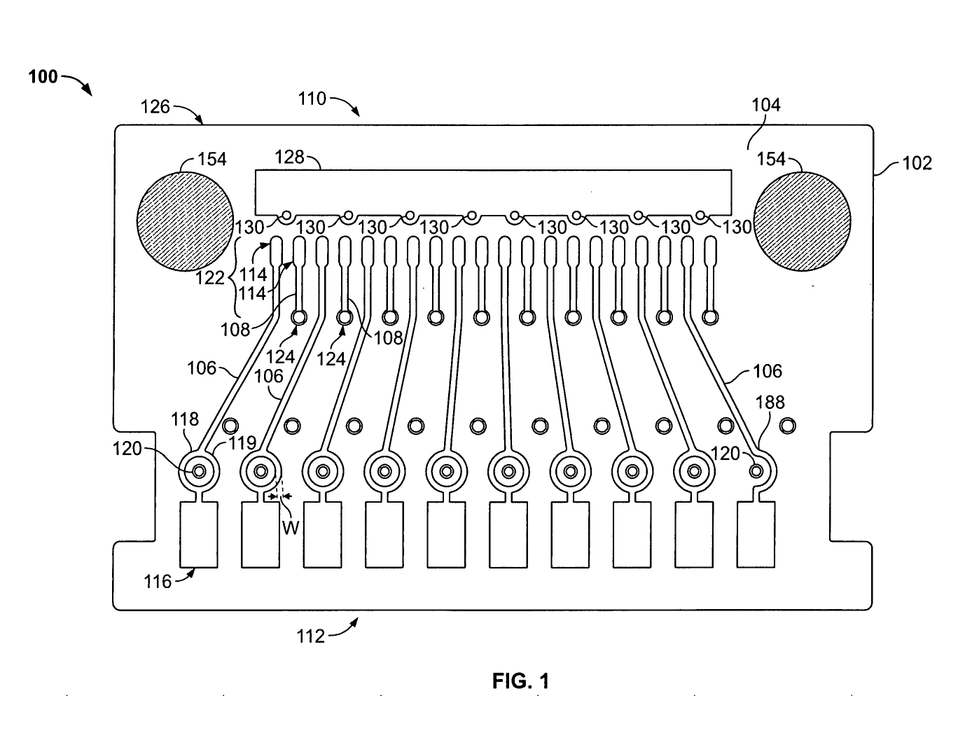

FIG. 1 illustrates a top layer 126 of a transition circuit board 100 which may be used to transition a cable to a connector that does not have an internal ground reference. The cable may be one or more ribbonized coaxial cables, although other types of cable may also be used. The circuit board 100 may be formed of layers which are further discussed below, such as one or more internal or intermediate layers and top and bottom outer layers. One or both of the top and bottom outer layers may convey signals between the cable and the connector while the intermediate layers are ground planes. Alternatively, the top layer of the circuit board 100 may convey signals while the bottom layer located on the opposite surface of the circuit board is a ground plane. Holes 154 may extend through the circuit board 100 to be used when mounting the circuit board 100 to another structure.

An outer edge 102 forms a perimeter around the circuit board 100. A cable receiving end 110 receives the coaxial or other cable (not shown). On an opposite side of the circuit board 100, contact mating end 112 receives insulation displacement contact pins (IDC pins) of an insulation displacement connector. The contact mating end 112 may alternatively be configured to receive contacts of a different type of connector which may not have an internal ground reference.

The top layer 126 may be formed of a dielectric material, such as fiberglass, and has an outer surface 104 provided thereon. Conductive material, such as copper, is provided on the outer surface 104 to form circuit traces to convey signals or grounds between the cable and connector, and to form ground links which connect the outer surface 104 to a ground plane within the circuit board 100. For example, the ground links may be plated through vias.

A ground bar 128 is formed proximate the cable receiving end 110 and is electrically connected to a ground plane (not shown) within the circuit board 100 by vias 130. Coaxial cables typically are provided with a braid or outside shield which, if more than one coaxial cable is being used, may be soldered together to form a single bar or rectangle. The coaxial cable(s) are then soldered to the ground bar 128.

A first set of circuit traces 106 extends on the outer surface 104 from proximate the cable receiving end 110 to proximate the contact mating end 112 on the top layer 126. A second set of circuit traces 108 extends on the outer surface 104 parallel to a first portion 122 of the first set of circuit traces 106 proximate the cable receiving end 110. Circuit traces within the first and second sets of circuit traces 106 and 108 alternate with one another. Each of the circuit traces 106 and 108 has a cable pad 114 for receiving a center conductor of the coaxial cable. Therefore, a separate center conductor may be soldered to each of the cable pads 114. Opposite the cable pad 114, each of the second set of circuit traces 108 connects to a via 124 which is plated through to the bottom layer of the circuit board 100, and thus is electrically connected to circuit traces on the bottom layer of the circuit board.

At the contact mating end 112 of the first set of circuit traces 106, a contact pad 116 receives a connector contact (not shown), such as an IDC pin. Each IDC pin may be soldered to its respective contact pad 116. Each circuit trace 106 may be split into first and second segments 118 and 119 which pass around opposite sides of via 120. Therefore, the first and second segments 118 and 119 are formed proximate or immediately adjacent to the via 120. The first and second segments 118 and 119 may be arcuate and arranged concentrically about the via 120. Alternatively, the via 120 may be formed as an oval, square, rectangle, hexagonal, tapered fore and aft, ellipsoidal, or other shape, and the first and second segments 118 and 119 may follow an outer contour of the via 120. By way of example, the first and second segments may be separated from the via 120 by approximately a width W of one of the first and second segments 118 and 119. Alternatively, the circuit trace 106 may not be split, but rather form a single line or segment 188 that may be arcuate along one side or follow an outer contour of the via 120. Each of the vias 120 is plated through to a ground plane (not shown) within the circuit board 100 which provides the ground reference for the top layer 126. The vias 120 are one example of a ground plane link or a ground link to the ground plane.

Each of the circuit traces 106 may be designated to convey signal or a reference ground. To render a circuit trace 106 electrically common with the ground plane, the first and/or second segments 118 and 119 (or segment 188) may be electrically joined with the respective via 120 located there-between using a conductive jumper material, such as solder. Therefore, the circuit board 100 can be easily “programmed” or customized by the user.

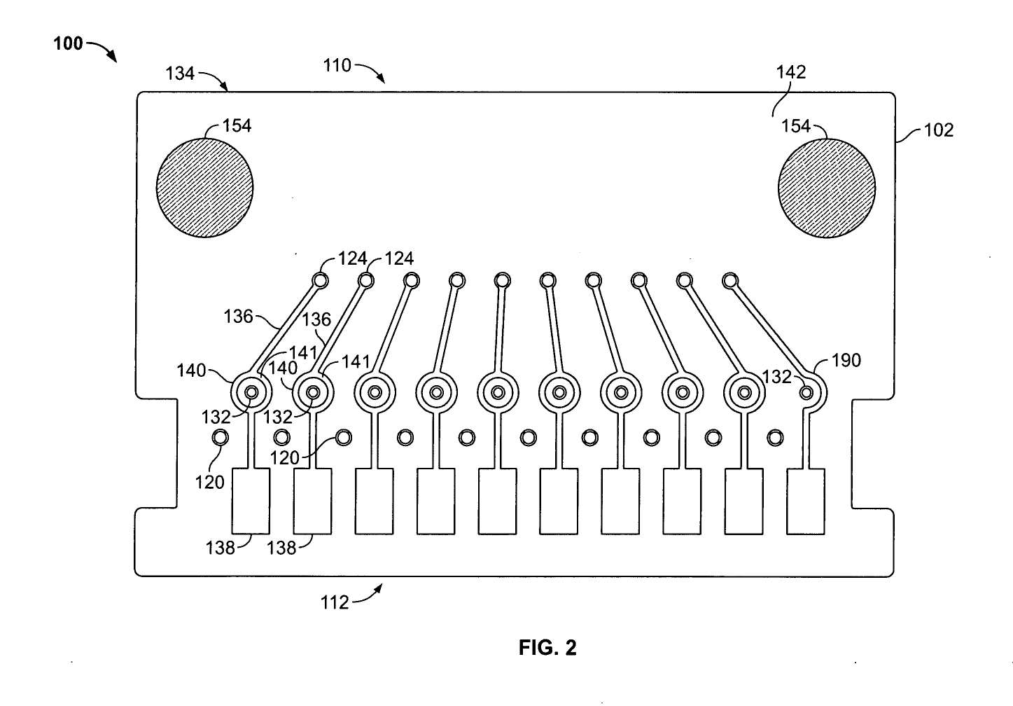

FIG. 2 illustrates a bottom layer 134 of the circuit board 100. The bottom layer 134 has an outer surface 142. A set of circuit traces 136 is formed on the outer surface 142 and extends from the vias 124 to contact pads 138 proximate the contact mating end 112. Each contact pad 138 is configured to receive a connector contact (not shown), such as an IDC pin.

An insulation displacement connector (not shown) has two rows of IDC pins which are offset or staggered with respect to each other. Therefore, the contact pads 138 are offset with respect to the contact pads 116 on the top layer 126. The IDC pins are pressed over the contact mating end 112 of the circuit board 100 with a first row of IDC pins interfacing with the contact pads 116 on the top layer 126 (FIG. 1) and a second row of IDC pins interfacing with the contact pads 138 on the bottom layer 134.

In one embodiment, each circuit trace 136 splits into first and second segments 140 and 141 which pass around opposite sides of via 132 which is plated through the circuit board 100 to electrically connect to a ground plane (not shown) within the circuit board 100. In another embodiment, a line or segment 190 of each circuit trace 136 may pass along one side of the via 120. The first and second segments 140 and 141 (or segment 190) and associated via 132 may be electrically connected with conductive jumper material to link the circuit trace 136 to the ground plane.

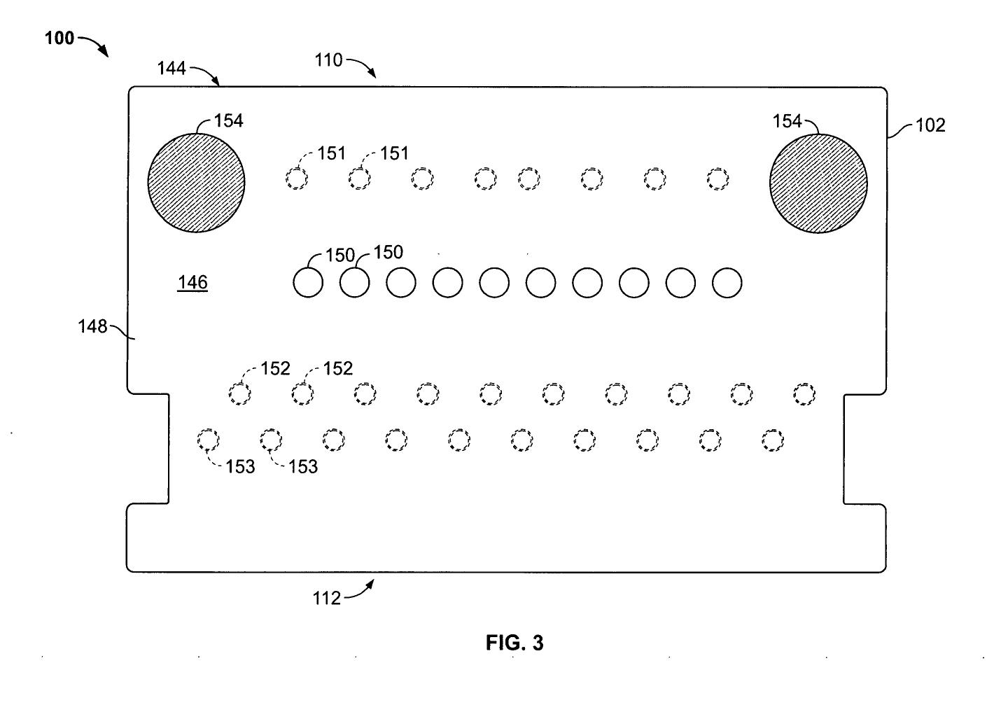

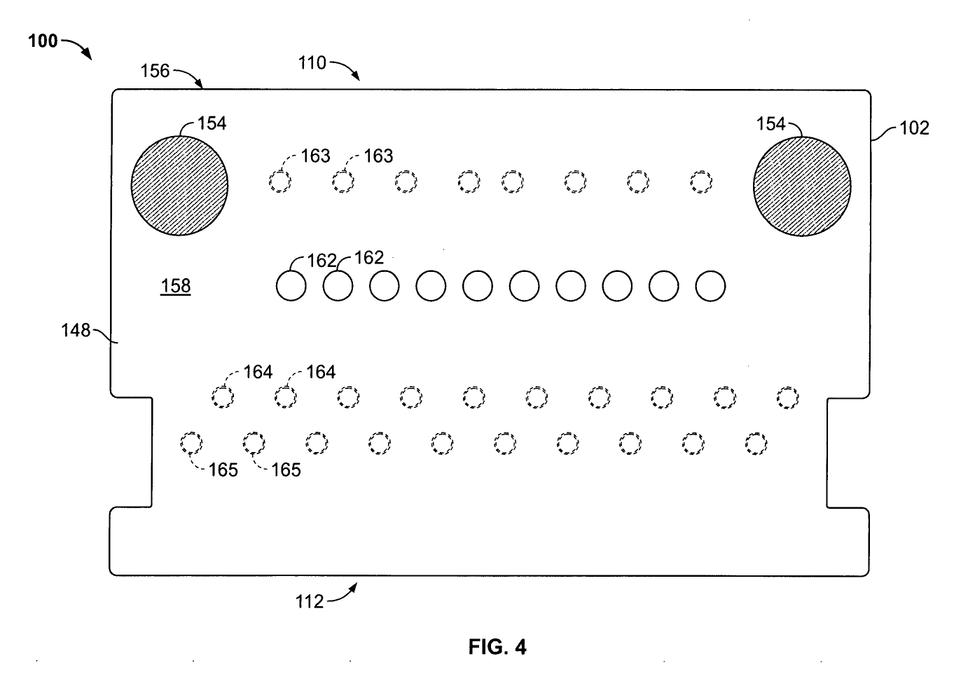

FIG. 3 illustrates a first ground plane 144 formed as an intermediate layer of the circuit board 100. The first ground plane 144 may be formed of a layer of conductive material 146 over a layer of dielectric material 148 which operates as a filler to separate the first ground plane 144 from a second ground plane (FIG. 4). The first ground plane 144 carries a ground reference level for the top layer 126. The conductive material 146 is removed from, or not applied to, areas 150 which completely surround the vias 124 (FIG. 1) that electrically connect circuit traces 108 on the top layer 126 (FIG. 1) to the circuit traces 136 on the bottom layer 134 (FIG. 2). The areas 150 may be circular in shape as illustrated, or may be another shape which completely surrounds the vias 124. Broken circles 151, 152 and 153 indicate where the plated through vias 130, 132 and 120, respectively, extend through the first ground plane 144.

FIG. 4 illustrates a second ground plane 156 formed as an intermediate layer of the circuit board 100. The second ground plane 156 may be formed of a layer of conductive material 158 which is applied to an opposite side of the dielectric material 148 as compared to the first ground plane 144. The second ground plane 156 carries a ground reference level for the bottom layer 134. The conductive material 158 is removed from, or not applied to, areas 162 which completely surround the vias 124 (FIG. 1). The areas 162 may be circular, square, or other shape. Broken circles 163, 164 and 165 indicate locations where the plated through vias 130, 132 and 120, respectively, extend through the second ground plane 156.

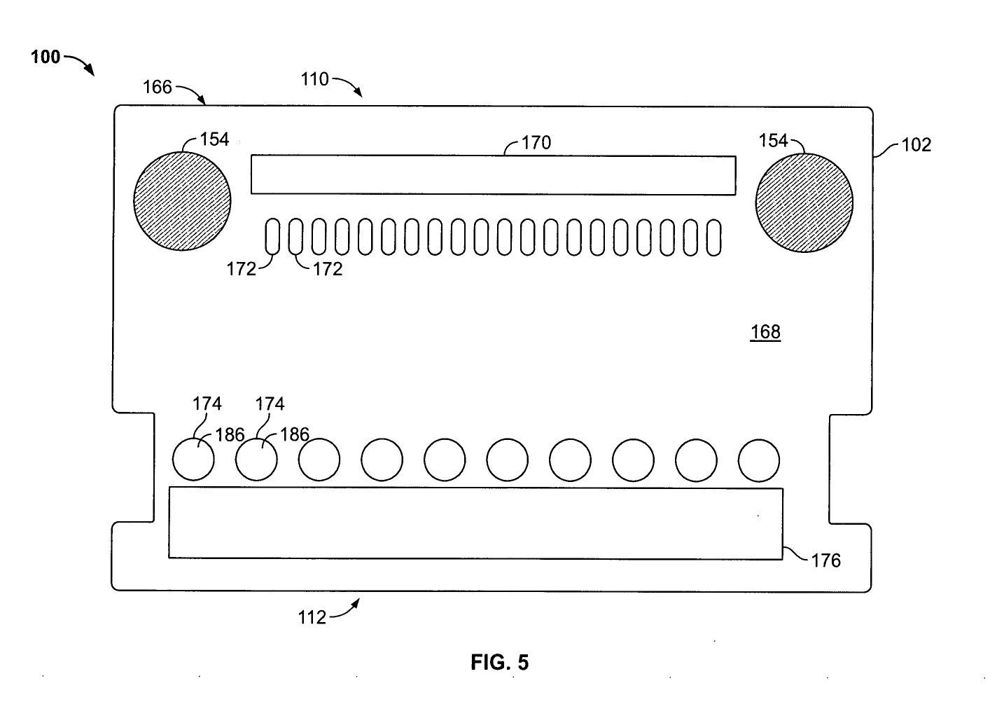

FIG. 5 illustrates a top solder mask 166 which may be applied over the top layer 126 of FIG. 1. The top solder mask 166 covers portions of the top layer 126 with a resistive coating 168 which prevents solder from adhering to the covered or coated portions. A ground bar mask aperture 170 is formed in the top solder mask 166 to expose the ground bar 128 (FIG. 1). Therefore, the ground bar 128 is not coated by the resistive coating 168 and will accept solder when the braid or shield of the coaxial cable is soldered thereto. Similarly, cable pad mask apertures 172 are formed in the top solder mask 166 to expose the cable pads 114. A contact pad mask aperture 176 is formed in the top solder mask 166 to expose the contact pads 116, allowing interconnection with the IDC pins.

Circuit trace mask apertures 174 are formed in the top solder mask 166 to expose uncoated portions 186 of the circuit traces 106 such as the first and second segments 118 and 119 and vias 120. The uncoated portions 186 of the circuit traces 106 accept solder or other conductive jumper material that may be applied within the circuit trace mask apertures 174 to render select circuit traces 106 electrically common with the ground plane 144 (FIG. 3). Each circuit trace mask aperture 174 is at least partially surrounded by coated portions of the top layer 126, and therefore adjacent circuit traces which carry signals will not be inadvertently tied to the ground plane 144.

Therefore, the desired circuit traces 106 may be linked to the ground plane 144 to obtain a configuration based on an application in which the circuit board 100 is to be used. For example, two different applications may require different pins to be connected to ground. The circuit board 100 can be customized for both applications by linking different circuit traces 106 to the ground plane 144.

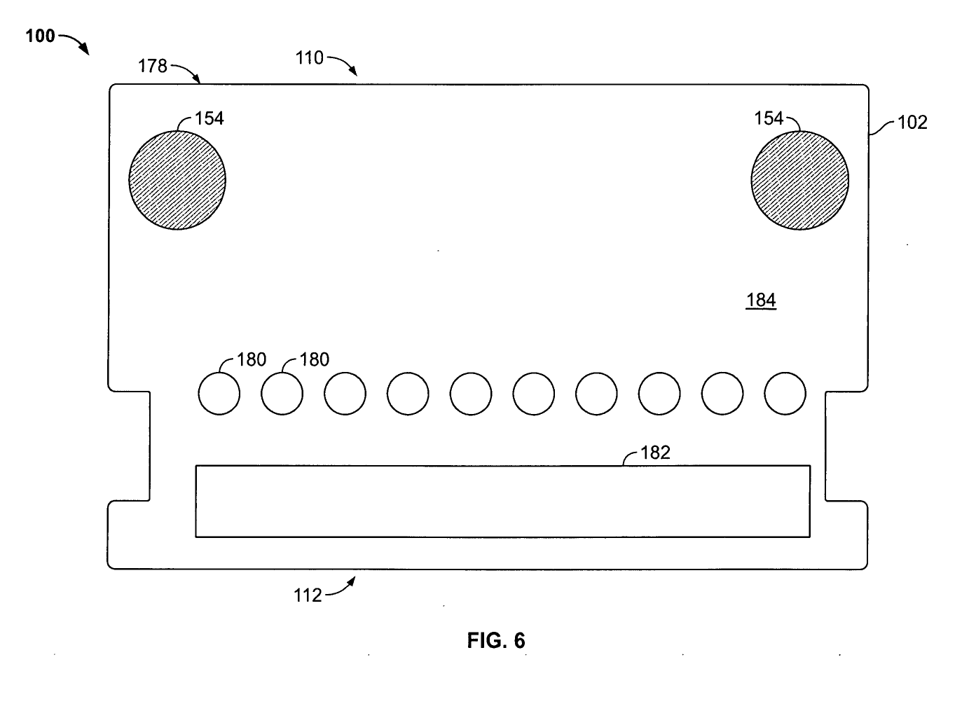

FIG. 6 illustrates a bottom solder mask 178 which is applied over the bottom layer 134 of FIG. 2. The bottom solder mask 178 covers portions of the bottom layer 134 with a resistive coating 184 which prevents solder from adhering to the covered or coated portions.

Bottom trace mask apertures 180 are formed to expose the first and second segments 140 and 141 and the vias 132 (FIG. 2). Conductive jumper material may be applied within one or more of the bottom trace mask apertures 180 to render a desired circuit trace 136 electrically common with the second ground plane 156. Bottom contact pad mask aperture 182 leaves the contact pads 138 uncoated by the resistive coating 184, allowing connection with the IDC pins.

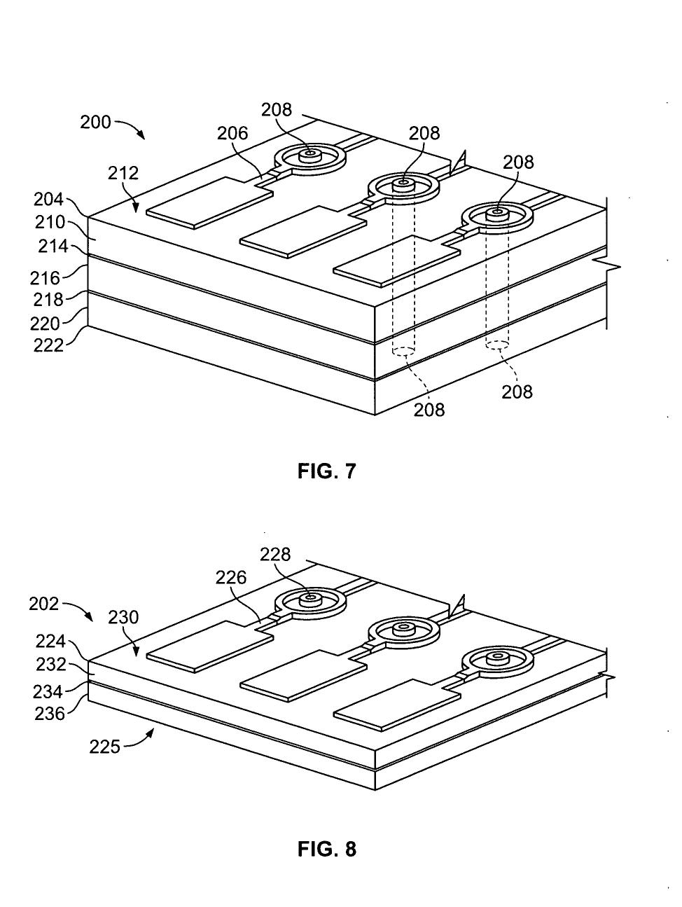

FIGS. 7 and 8 illustrate multilayer circuit boards 200 and 202 which may be used to transition a cable to a connector which does not have an internal ground reference. The circuit board 200 has four conductive layers and the circuit board 202 has either two or three conductive layers. The conductive layers may be formed of copper.

Turning to the circuit board 200 of FIG. 7, the four conductive layers may be formed by seven layers of lamination. Top layer 204 is the first conductive layer in the circuit board 200 and has circuit traces 206 and ground links 208 formed on an outer surface 212 of dielectric material 210. Therefore, the top layer 204 does not completely cover the outer surface 212. The ground links 208 may be plated through vias or holes extending through the circuit board 200. The solder mask, such as top solder mask 166 (FIG. 5) which is coated over portions of the circuit traces 206, ground links 208 and the outer surface 212 is not typically considered a separate layer.

A first ground plane 214 is the second conductive layer in the circuit board 200 and is laminated on a bottom side of the dielectric material 210. The first ground plane 214 carries a ground reference level for the top layer 204. Dielectric material 216 is applied between the first ground plane 214 and second ground plane 218, which is the third conductive layer in the circuit board 200. The first and second ground planes 214 and 218 are intermediate layers within the circuit board 200. Dielectric material separates the second ground plane 218 and bottom layer 222, which is the fourth conductive layer in the circuit board 200. Circuit traces and ground links (not shown) are formed on an outer surface of the bottom layer 222 as in FIG. 2, forming the fifth conductive layer. The bottom solder mask 178 (FIG. 6) is coated over portions of the circuit traces, ground links and the outer surface of the bottom layer 222. The second ground plane 218 carries a ground reference level for the bottom layer 222.

Turning to FIG. 8, the circuit board 202 has either two conductive layers which may be formed by three or four layers of lamination, or three conductive layers which may be formed by five layers of lamination. Top layer 224 is the first conductive layer in the circuit board 202 and has circuit traces 226 and ground links 228 formed on an outer surface 230 of dielectric material 232. The top solder mask 166 (FIG. 5) is coated over portions of the circuit traces 226, ground links 228 and the outer surface 230. A ground plane 234 is the second conductive layer in the circuit board 202 and carries the ground reference level for the top layer 224. In one embodiment, the ground plane 234 is located on a back surface 225 of the circuit board 202 that is opposite to the top surface 224. Optionally, dielectric material 236 may be formed on an opposite side of the ground plane 234 (fourth layer of lamination) to prevent shorting the ground plane 234 to other structures. In another embodiment, circuit traces and ground links (not shown) are formed on the back surface 225, forming the third conductive layer.

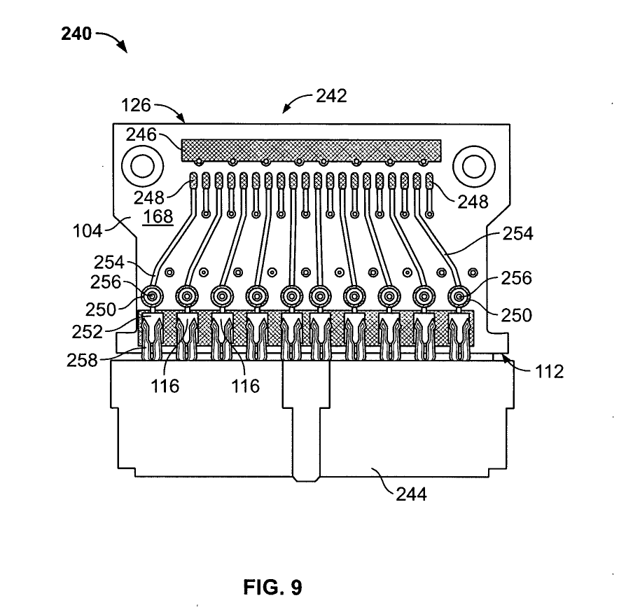

FIG. 9 illustrates an assembly 240 of a circuit board 242 and an insulation displacement connector 244 which has been pressed thereon. The top layer 126 (FIG. 1) of the circuit board 242 is illustrated and the resistive coating 168 (FIG. 5) has been coated over portions of circuit traces 254, vias 256 and the outer surface 104.

Referring also to FIGS. 1 and 5, portions of the outer surface 104 of the circuit board 242 may be covered prior to coating with the resistive coating 168, such as with a stainless steel mask (not shown) or other masking agent known in the art. First portion 246 corresponding to the ground bar mask aperture 170 (FIG. 5), second portions 248 corresponding to the cable pad mask apertures 172, third portions 250 corresponding to the circuit trace mask apertures 174, and fourth portion 252 corresponding to the contact pad mask aperture 176 may all be covered with the masking agent to prevent coating of the first, second, third and fourth portions 246, 248, 250 and 252 with the resistive coating 168. The uncoated portions may receive and retain solder, wherein the coated portions do not retain solder.

After the resistive coating 168 has been applied, the circuit board 242 may be configured or programmed to be used in a particular application. Solder paste may be applied and then reflowed, or solder may be directly applied, to one or more of the third portions 250 to electrically connect the desired circuit trace 254 to its associated via 256, which is plated through to the ground plane (not shown).

The insulation displacement connector 244 may be pressed over the contact mating end 112 of the circuit board 242. Bifurcated IDC pins 258 extend over the contact pads 116, which are not coated with the resistive coating 168. The IDC pins 258 may then be soldered to the contacts pads 116.

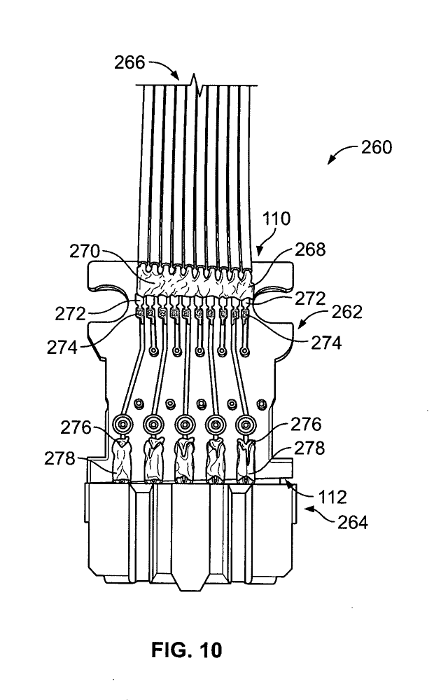

FIG. 10 illustrates an assembly 260 of a circuit board 262 with an insulation displacement connector 264 and ribbonized coaxial cable 266 interconnected thereto. As in FIG. 9, the resistive coating 168 has been coated over portions of circuit traces, vias or ground links and the outer surface of the circuit board 262. The coaxial cable 266 is formed of a single cable, but multiple cables may also be used.

To interconnect the coaxial cable 266 to the circuit board 262, a braid or outer shield 270 of the coaxial cable 266 is soldered to ground bar 268 proximate the cable receiving end 10. Center conductors 272 of the coaxial cable 266 are soldered to cable pads 274. The insulation displacement connector 264 is pressed over the contact mating end 112 of the circuit board 262. As with FIG. 9, bifurcated IDC pins 278 extend over, and are soldered to, contact pads 276.

While the invention has been described in terms of various specific embodiments, those skilled in the art will recognize that the invention can be practiced with modification within the spirit and scope of the claims.

What is claimed is:

1. A circuit board for transitioning a cable to a connector, comprising:
a circuit board having an outer surface;
a circuit trace provided on the outer surface of the circuit board and having a cable pad and a contact pad provided at different ends of the outer surface;
a ground plane held by the circuit board;
a ground link provided on the outer surface of the circuit board connected to the ground plane, the circuit trace and the ground link being located immediately adjacent one another;
a resistive coating provided over the circuit trace and the outer surface of the circuit board, the resistive coating having a mask aperture there-through exposing an uncoated portion of the circuit trace and exposing the ground link to the ground plane; and
a conductive jumper material provided on the uncoated portion of the circuit trace and the ground link to render the circuit trace electrically common with the ground plane.

2. The circuit board of claim 1, wherein the circuit board has a cable receiving end and a contact mating end, the cable receiving end being configured to be joined to cables terminated at the circuit board, the contact mating end being configured to engage contacts.

3. The circuit board of claim 1, wherein the ground link constitutes a via that extends at least partially into the circuit board from the outer surface to the ground plane.

4. The circuit board of claim 1, wherein the ground plane is located at one of an intermediate layer within the circuit board and on a back surface of the circuit board that is opposite to the outer surface having the circuit trace.

5. The circuit board of claim 1, wherein the ground plane is located away from the outer surface of the circuit board.

6. The circuit board of claim 1, wherein the uncoated portion of the circuit trace is split into segments that pass around opposite sides of the ground link to the ground plane.

7. The circuit board of claim 1, wherein the uncoated portion of the circuit trace is split into arcuate segments that are arranged concentrically about the ground link to the ground plane.

8. The circuit board of claim 1, wherein the ground link to the ground plane constitutes a via and the jumper material constitutes solder that shorts the circuit trace to the ground plane.

9. An electrical connector, comprising:
a connector;
a circuit board having an outer surface and having a cable receiving end and a contact mating end, the cable receiving end being configured to be joined to cables terminated at the circuit board, the contact mating end being configured to engage contacts;
a circuit trace provided on the outer surface of the circuit board and having a cable pad and a contact pad provided at different ends of the outer surface;
a ground plane held by the circuit board;
a ground link provided on the outer surface of the circuit board connected to the ground plane, the circuit trace and the ground link being located immediately adjacent to one another;
a resistive coating provided over the circuit trace and outer surface of the circuit board, the resistive coating having a mask aperture there-through exposing an uncoated portion of the circuit trace and exposing the ground link to the ground plane; and
a conductive jumper material provided on the uncoated portion of the circuit trace and the ground link to render the circuit trace electrically common with the ground plane.

10. The connector of claim 9, wherein the ground link to the ground plane constitutes a via that extends at least partially into the circuit board from the outer surface to the ground plane.

11. The connector of claim 9, wherein the uncoated portion of the circuit trace is split into arcuate segments that are arranged concentrically about the ground link to the ground plane.

12. The connector of claim 9, wherein the ground link to the ground plane constitutes a via and the jumper material constitutes solder that shorts the circuit trace to the ground plane.

13. A method of manufacturing a circuit board for transitioning a coaxial cable to a connector, comprising:
forming a circuit board with a ground plane;
providing a circuit trace on an outer surface of a circuit board, the circuit trace having a cable pad and a contact pad at different ends of the outer surface;
providing a ground link between the outer surface and the ground plane;
coating the circuit trace and outer surface of the circuit board with a resistive coating;
covering a portion of the circuit trace during the coating step to prevent the resistive coating from covering the portion of the circuit trace to form an uncoated portion of the circuit trace; and
covering the ground link during the coating step to prevent the resistive coating from covering the ground link, the ground link and the uncoated portion of the circuit trace being located immediately adjacent to one another.

14. The method of claim 13, further comprising bonding a conductive jumper material to the uncoated portion of the circuit trace and to the ground link to render the circuit trace electrically common with the ground plane.

15. The method of claim 13, further comprising providing multiple circuit traces on the outer surface of the circuit board and bonding a conductive jumper material to the uncoated portion of a select one of the circuit traces and a corresponding ground link based on an application in which the circuit board is to be used.

16. The method of claim 13, wherein the circuit board has a cable receiving end and a contact mating end, the cable receiving end being configured to be joined to cables terminated at the circuit board, the contact mating end being configured to engage contacts.

17. The method of claim 13, wherein the ground link includes a via that extends at least partially into the circuit board from the outer surface to the ground plane.

18. The method of claim 13, wherein the uncoated portion of the circuit trace is split into segments that pass around opposite sides of the ground link.

19. The method of claim 13, wherein the uncoated portion of the circuit trace is split into arcuate segments that are arranged concentrically about the ground link.

20. The method of claim 13, wherein the ground link constitutes a via and the jumper material constitutes solder that shorts the circuit trace to the ground plane.
